(19) United States
(12) Patent Application Publication
(10) Pub. No.: US 2016/0189851 A1
(43) Pub. Date: Jun. 30, 2016

(54) ELECTRONIC COMPONENT AND BOARD HAVING THE SAME

(71) Applicant: SAMSUNG ELECTRO-MECHANICS CO., LTD., Suwon-Si (KR)

(72) Inventor: Heoung Sub LEE, Suwon-Si (KR)

(21) Appl. No.: 14/944,179

(22) Filed: Nov. 17, 2015

(30) Foreign Application Priority Data
Dec. 24, 2014 (KR) 10-2014-0189114

(51) Int. Cl. H01F 27/28; H01F 27/245; H01F 27/255; H01F 27/29; H05K 1/18

(52) U.S. Cl. CPC H01F 27/2804; H01F 27/29; H05K 1/181; H01F 27/255; H01F 27/245; H01F 2027/2809; H05K 2201/1003

(57) ABSTRACT

An electronic component includes a multilayer body including a plurality of magnetic or dielectric layers and a coil part including a plurality of conductor patterns and conductive vias electrically connecting the plurality of conductor patterns to each other. External electrodes are disposed on outer surfaces of the multilayer body and electrically connected to the coil part. Adjacent conductor patterns have at least one among the magnetic or dielectric layers interposed therebetween. Buffer layers having a permittivity lower than that of the multilayer body are disposed at interfaces between the conductor patterns and the magnetic or dielectric layers.

### CROSS-REFERENCE TO RELATED APPLICATION

This application claims the benefit of priority to Korean Patent Application No. 10-2014-0189114, filed on Dec. 24, 2014 with the Korean Intellectual Property Office, the entirety of which is incorporated herein by reference.

### TECHNICAL FIELD

The present disclosure relates to an electronic component and a board having the same.

### BACKGROUND

An inductor, a passive element configuring an electronic circuit, together with a resistor and a capacitor, is used as a component for removing noise or configuring an LC resonant circuit.

Inductors may be classified into several types, such as a multilayer inductor, a wire wound inductor, a thin film inductor, and the like, depending on a structure thereof. Among these, the multilayer inductor is in widespread use.

A general multilayer inductor has a structure in which a plurality of magnetic layers having internal conductor patterns formed thereon are stacked. The internal conductor patterns are sequentially connected to each other by via electrodes formed in respective magnetic layers to form a coil structure, thereby obtaining characteristics such as target inductance and target impedance.

Parasitic capacitance is inevitably generated in multilayer inductors. Parasitic capacitance C is generated in parallel with inductance L to generate parallel resonance in a high frequency band.

Parasitic capacitance does not have an influence on the multilayer inductor in a low frequency band, but causes a Q value of the multilayer inductor to be gradually decreased toward a resonance point in a high frequency band.

In the past, inductors have been evaluated only using a reference frequency band of 100 MHz. However, since frequency bands of 800 MHz, 1.8 GHz, and 2.5 GHz are actually used, demand for an improved quality (Q) factor in these conditions has increased.

Since parasitic capacitance is in proportion to permittivity of a material, research into technology of adjusting permittivity in inductors in order to improve Q factors has been required.

### SUMMARY

An aspect of the present disclosure provides an electronic component of which parasitic capacitance is decreased by lowering permittivity, and a board having the same.

According to an aspect of the present disclosure, an electronic component includes a multilayer body including a plurality of magnetic or dielectric layers and a coil part including a plurality of conductor patterns and conductive vias electrically connecting the plurality of conductor patterns to each other. External electrodes are disposed on outer surfaces of the multilayer body and electrically connected to the coil part. Adjacent conductor patterns have at least one among the magnetic or dielectric layers interposed therebetween. Buffer layers having a permittivity lower than that of the multilayer body are disposed at interfaces between the conductor patterns and the magnetic or dielectric layers.

A ratio of a permittivity of the multilayer body to the permittivity of the buffer layer may be 4 to 7.

The buffer layer may be an air gap layer having a relative permittivity of 1.0.

The magnetic or dielectric layers may contain ferrite or magnetic metal powder.

According to another aspect of the present disclosure, an electronic component includes: a multilayer body in which a plurality of magnetic or dielectric layers are stacked and a coil part including a plurality of conductor patterns and conductive vias electrically connecting the plurality of conductor patterns to each other. External electrodes are disposed on outer surfaces of the multilayer body and electrically connected to the coil part. The magnetic or dielectric layers are disposed between the plurality of conductor patterns, and air gap layers are disposed at interfaces between the conductor patterns and the magnetic or dielectric layers.

According to another aspect of the present disclosure, a board having an electronic component includes a printed circuit board on which first and second electrode pads are disposed and the electronic component, as described above, mounted on the printed circuit board.

### BRIEF DESCRIPTION OF DRAWINGS

The above and other aspects, features and advantages of the present disclosure will be more clearly understood from the following detailed description taken in conjunction with the accompanying drawings, in which:

FIG. 1 is a schematic perspective view illustrating an electronic component including an internal coil part according to an exemplary embodiment in the present disclosure;

FIG. 2 is a cross-sectional view of the electronic component according to an exemplary embodiment in the present disclosure;

FIG. 3 is an enlarged view of part A of FIG. 2;

FIG. 4 is a perspective view illustrating a board in which the electronic component of FIG. 1 is mounted on a printed circuit board; and

FIG. 5 is a graph illustrating comparison results of quality (Q) factors depending on frequencies, according to Inventive Example and Comparative Example.

### DETAILED DESCRIPTION

Hereinafter, embodiments of the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

### Electronic Component

An electronic component, according to an exemplary embodiment, may be an inductor, a bead, a filter, or the like, having conductor patterns formed on magnetic or dielectric layers.

Hereinafter, an electronic component particularly, a multilayer inductor, according to an exemplary embodiment, will be described. However, the electronic component according to exemplary embodiments is not limited thereto.

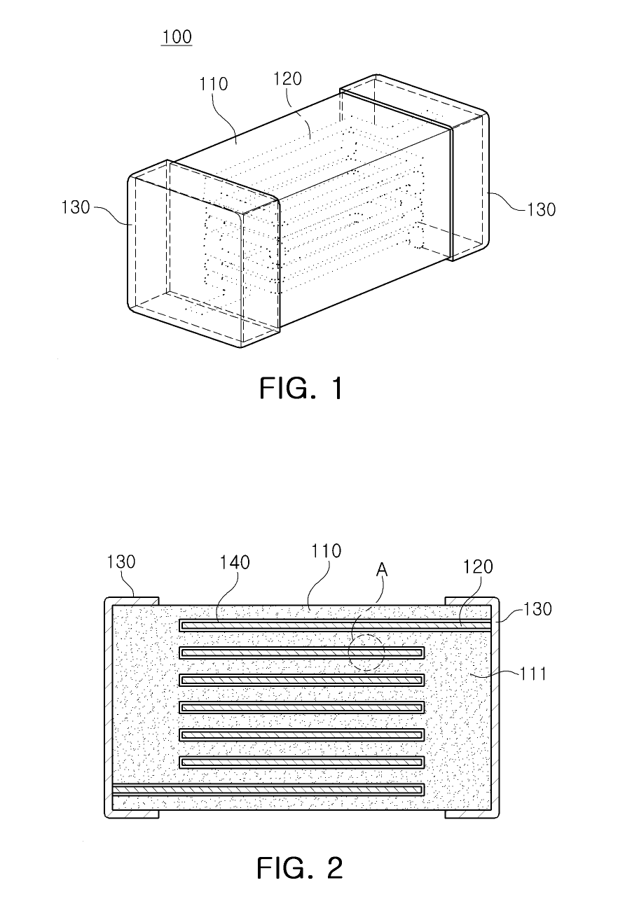

FIG. 1 is a schematic perspective view illustrating an electronic component including an internal coil part according to an exemplary embodiment.

FIG. 2 is a cross-sectional view of the electronic component according to the exemplary embodiment.

An electronic component 100 according to an exemplary embodiment may include: a multilayer body 110 in which a plurality of magnetic or dielectric layers 111 are stacked and a coil part 120 including a plurality of conductor patterns and conductive vias electrically connecting the plurality of conductor patterns to each other is embedded; and external electrodes 130 disposed on outer surfaces of the multilayer body 110 and electrically connected to the coil part 120.

The multilayer body 110 may be formed by stacking the plurality of magnetic or dielectric layers 111 in a thickness direction and then sintering the plurality of magnetic or dielectric layers 111. The shape and dimensions of the multilayer body 110 and the number of stacked magnetic or dielectric layers 111 are not limited to those illustrated in FIGS. 1 and 2.

A shape of the multilayer body 110 is not particularly limited, but may be, for example, hexahedral.

In the present embodiment, for convenience of explanation, upper and lower surfaces of the multilayer body 110 refer to two surfaces of the multilayer body 110 opposing each other in a thickness direction. Both end surfaces of the multilayer body 110 refer to two surfaces of the multilayer body 110 connecting the upper and lower surfaces to each other and opposing each other in a length direction. Both side surfaces of the multilayer body 110 refer to two surfaces of the multilayer body 110 perpendicularly intersecting with both end surfaces of the multilayer body 110 and opposing each other in a width direction.

The magnetic or dielectric layers 111 may contain ferrite or magnetic metal powder. The ferrite may be, for example, Mn—Zn-based ferrite, Ni—Zn-based ferrite, Ni—Zn—Cu-based ferrite, Mn—Mg-based ferrite, Ba-based ferrite, or Li-based ferrite.

The magnetic metal powder may contain one or more selected from the group consisting of Fe, Si, Cr, Al, and Ni. For example, the magnetic metal powder may include a Fe—Si—B—Cr-based amorphous metal, but is not limited thereto.

The magnetic metal powder may have a particle size of 0.1 to 30 μm, and may be dispersed in a thermosetting resin such as an epoxy resin or polyimide.

When the multilayer body 110 includes the dielectric layers 111, the dielectric layers 111 may be selected to have one or more selected from the group consisting of TiO₂, ZrO₂, Al₂O₃, and ZnTiO₃.

Conductor patterns for forming the coil part 120 may be formed on surfaces of the plurality of magnetic or dielectric layers 111, and the conductive vias electrically connecting the conductor patterns positioned on and below the magnetic or dielectric layers 111 to each other may be formed to penetrate through the magnetic or dielectric layers 111.

Therefore, ends of the conductor patterns formed on respective magnetic or dielectric layers may be electrically connected to each other by the conductive vias formed in the magnetic or dielectric layers to form the coil part 120.

In addition, both ends of the coil part 120 may be exposed to the outside of the multilayer body 110, such that they may be electrically connected to a pair of external electrodes 130 disposed on outer surfaces of the multilayer body 110, respectively.

In particular, both ends of the coil part 120 may be exposed through opposite end surfaces of the multilayer body 110, respectively, and the pair of external electrodes 130 may be formed on opposite end surfaces of the multilayer body 110 through which the coil part 120 is exposed.

The conductor patterns may be formed by printing, applying, depositing, and sputtering a conductive paste for forming the conductor patterns on sheets for forming the magnetic or dielectric layers. However, a method of forming the conductor patterns is not limited thereto.

The conductive vias may be formed by forming through-holes in respective sheets in the thickness direction and then filling the through-holes with a conductive paste, or the like. However, a method of forming the conductive vias is not limited thereto.

In addition, a conductive metal contained in the conductive paste for forming the conductor pattern may be, for example, any one of silver (Ag), palladium (Pd), platinum (Pt), nickel (Ni), and copper (Cu), or an alloy thereof. However, the conductive metal contained in the conductive paste is not limited thereto.

However, when a precious metal such as silver (Ag), palladium (Pd), platinum (Pt), or the like, is used, costs may be increased. Therefore, copper (Cu) or nickel (Ni), relatively inexpensive materials, among the above-mentioned metals, may be used as a material of the coil part.

The external electrodes 130 may be electrically connected to both ends of the coil part 120 exposed to the outside of the multilayer body 110, respectively.

These external electrodes 130 may be formed on the magnetic body 110 using a conductive paste by various methods such as a dipping method, a printing method, a depositing method or a sputtering method.

The conductive paste may be formed of a material including one of, for example, silver (Ag), copper (Cu), and a copper (Cu) alloy, but is not limited thereto.

A nickel (Ni) plating layer (not illustrated) and a tin (Sn) plating layer (not illustrated) maybe further formed on outer surfaces of the external electrodes 130.

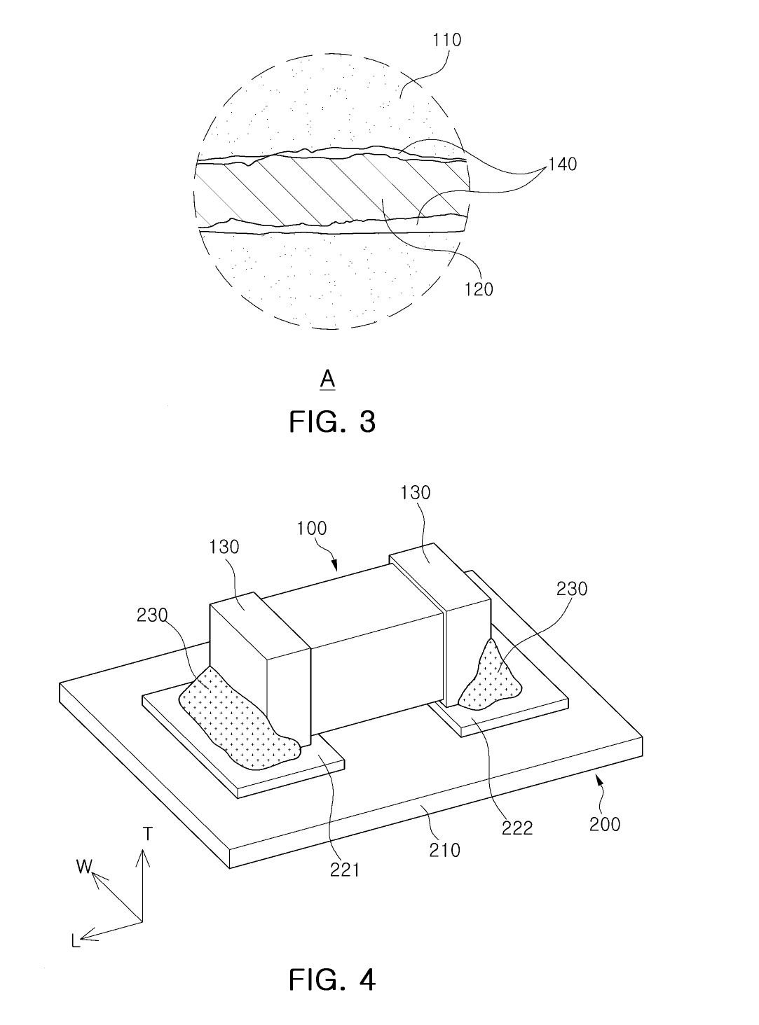

FIG. 3 is an enlarged view of part A of FIG. 2. Referring to FIG. 3, the magnetic or dielectric layers may be disposed between the plurality of conductor patterns, and buffer layers 140 having permittivity lower than that of the multilayer body 110 may be disposed at interfaces between the conductor patterns and the magnetic or dielectric layers.

Generally, parasitic capacitance is inevitably generated in the multilayer inductor. Parasitic capacitance C is generated in parallel with inductance L to generate parallel resonance in a high frequency band.

That is, parasitic capacitance does not have an influence on the multilayer inductor in a low frequency band, but causes a Q value of the multilayer inductor to be gradually decreased toward a resonance point in a high frequency band.

In the past, inductors have been evaluated only using a reference of 100 MHz. However, since frequency bands of 800 MHz, 1.8 GHz, and 2.5 GHz are actually used, demand for an improved quality (Q) factor in these conditions has increased.

According to an exemplary embodiment, the buffer layers 140 having the permittivity lower than that of the multilayer body 110 may be disposed at the interfaces between the conductor patterns and the magnetic or dielectric layers, such that effective permittivity of the electronic component 100 may be decreased, thereby significantly decreasing parasitic capacitance of the electronic component 100.

The buffer layer 140 is not particularly limited, but may be, for example, an air gap layer. Relative permittivity of the air gap layer, which is a ratio of permittivity to vacuum, may be 1.0.

According to an exemplary embodiment, a ratio of the permittivity of the multilayer body 110 to the permittivity of the buffer layer 140 may be 4 to 7, for example, 5 to 6.

The air gap layers, which are the buffer layers 140, may be disposed at the interfaces between the conductor patterns and the magnetic or dielectric layers and may be disposed on both of upper and lower surfaces of the conductor patterns.

In addition, the air gap layers, which are the buffer layers 140, may be disposed on the entirety of the interfaces between the conductor patterns and the magnetic or dielectric layers, but are not limited thereto. For example, the air gap layers, which are the buffer layers 140, may also be disposed on only portions of the upper and lower surfaces of the conductor patterns.

In a case in which the air gap layers, which are the buffer layers 140, are disposed on the entirety of the interfaces between the conductor patterns and the magnetic or dielectric layers, an effect of decreasing parasitic capacitance of the electronic component may be excellent, such that a Q factor improvement effect of the electronic component may be increased.

Relative permittivity of the magnetic or dielectric layers configuring the multilayer body 110, a ratio of permittivity to vacuum, may be about 5 to 6. Relative permittivity of the air gap layers corresponding to the buffer layers 140 disposed at the interfaces between the conductor patterns and the magnetic or dielectric layers, a ratio of permittivity to vacuum, may be 1.0. Therefore, the buffer layers having low permittivity may be formed between internal conductor patterns, thereby decreasing the parasitic capacitance of the electronic component.

In a case of decreasing the parasitic capacitance of the electronic component by disposing the buffer layers 140 having permittivity lower than that of the multilayer body 110 at the interfaces between the conductor patterns and the magnetic or dielectric layers, a Q factor of the electronic component may be improved.

Particularly, in a high frequency band of about 1 GHz, a Q value may be unexpectedly increased by about 12% in an Inventive Example in which the buffer layers 140 having permittivity lower than that of the multilayer body 110 are provided as compared with a Comparative Example in which the buffer layers are not provided.

An electronic component according to another exemplary embodiment may include a multilayer body 110 in which a plurality of magnetic or dielectric layers 111 are stacked and a coil part 120 including a plurality of conductor patterns and conductive vias electrically connecting the plurality of conductor patterns to each other is embedded. External electrodes 130 may be disposed on outer surfaces of the multilayer body 110 and electrically connected to the coil part 120. The magnetic or dielectric layers may be disposed between the plurality of conductor patterns, and air gap layers 140 may be disposed at interfaces between the conductor patterns and the magnetic or dielectric layers.

According to another exemplary embodiment, a ratio of permittivity of the multilayer body 110 to permittivity of the air gap layer 140 may be 4 to 7, for example, 5 to 6.

Next, a method of manufacturing an electronic component according to an exemplary embodiment will be described. However, a method of manufacturing an electronic component is not limited thereto.

The electronic component, particularly, a multilayer inductor, according to an exemplary embodiment, may be manufactured as described below.

Slurry containing ferritic or magnetic metal powder may be applied to carrier films and be dried to prepare a plurality of magnetic green sheets.

The ferrite may be, for example, Mn—Zn-based ferrite, Ni—Zn-based ferrite, Ni—Zn—Cu-based ferrite, Mn—Mg-based ferrite, Ba-based ferrite, or Li-based ferrite.

The magnetic metal powder may contain one or more selected from the group consisting of Fe, Si, Cr, Al, and Ni. For example, the magnetic metal powder may be a Fe—Si—B—Cr-based amorphous metal, but is not limited thereto.

The magnetic metal powder may have a particle size of 0.1 to 30 μm and may be dispersed in a thermosetting resin such as an epoxy resin or polyimide.

A conductive paste may be applied to the magnetic green sheets using a screen to form conductive patterns.

In addition, ferrite slurry may be applied to a portion of the magnetic green sheet in the vicinity of the conductive pattern to be on the same level as the conductive pattern, thereby forming a single multilayer carrier.

A plurality of multilayer carriers on which the conductive patterns are formed may be repeatedly stacked so that the conductive patterns are electrically connected to each other, thereby forming a coil pattern in a stacking direction.

Here, via electrodes may be formed in the magnetic green sheets, such that upper and lower conductive patterns may be electrically connected to each other with each of the magnetic green sheets interposed therebetween.

The multilayer carriers on which the conductive patterns are formed may be repeatedly stacked to form a laminate. Then, the laminate may be sintered to form the multilayer body.

The buffer layers having permittivity lower than that of the multilayer body may be disposed at the interfaces between the conductor patterns and the magnetic or dielectric layers in the multilayer body.

The buffer layer may be the air gap layer.

The buffer layers, particularly, the air gap layers may be formed by forming the conductor patterns at a sintering temperature lower than that of the magnetic or dielectric layers, thereby allowing the conductor patterns to have a sintering contraction rate larger than that of the magnetic or dielectric layers.

The method of forming the air gap layers is not necessarily limited to the above-mentioned method, and controlling a sintering contraction rate to form the air gap layers at the interfaces between the conductor patterns and the magnetic or dielectric layers may be performed using various methods.

The air gap layers having permittivity lower than that of the multilayer body may be formed at the interfaces between the conductor patterns and the magnetic or dielectric layers in the multilayer body by controlling the sintering contraction rate, as described above, thereby decreasing parasitic capacitance.

Therefore, the Q factor of the electronic component in a high frequency band may be improved.

The external electrodes may be formed on the outer surfaces of the multilayer body to be electrically connected to both ends of the coil part exposed to the outside of the multilayer body, respectively.

The external electrodes 130 may be formed on the magnetic body using a conductive paste by various methods such as a dipping method, a printing method, a depositing method, or a sputtering method.

The conductive paste may be formed of a material including one of, for example, silver (Ag), copper (Cu), and a copper (Cu) alloy, but is not limited thereto. A nickel (Ni) plating layer (not illustrated) and a tin (Sn) plating layer (not illustrated) may be further formed on outer surfaces of the external electrodes.

### Board Having Electronic Component

FIG. 4 is a perspective view illustrating a board in which the electronic component of FIG. 1 is mounted on a printed circuit board.

Referring to FIG. 4, a board 200 having an electronic component 100 according to an exemplary embodiment may include a printed circuit board 210 on which the electronic component 100 is mounted, and first and second electrode pads 221 and 222 formed on an upper surface of the printed circuit board 210 to be spaced apart from each other.

Here, the external electrodes 130 disposed on both end surfaces of the electronic component 100 in the length direction may be electrically connected to the printed circuit board 210 by solders 230 in a state in which they are positioned to contact the first and second electrode pads 221 and 222, respectively.

The internal coil part 120 of the electronic component 100 mounted on the printed circuit board 210 may be disposed to be parallel to a mounting surface of the printed circuit board 210.

Descriptions of features overlapped with those of the electronic component according to the previous exemplary embodiment will be omitted.

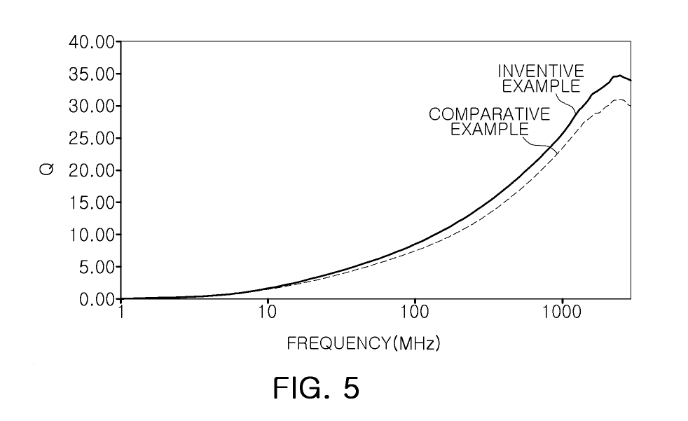

FIG. 5 is a graph illustrating comparison results of quality (Q) factors depending on frequencies, according to the Inventive Example and the Comparative Example.

Referring to FIG. 5, it can be seen that the Q factor is improved in the Inventive Example in which the buffer layers or the air gap layers having permittivity lower than that of the multilayer body are disposed at the interfaces between the conductor patterns and the magnetic or dielectric layers as compared with the Comparative Example in which the buffer layers or the air gap layers are not provided.

That is, in a high frequency band of about 1 GHz, a Q value may be unexpectedly increased by about 12% in the Inventive Example in which the buffer layers or the air gap layers having permittivity lower than that of the multilayer body are provided as compared with the Comparative Example in which the buffer layers or the air gap layers are not provided.

As set forth above, according to exemplary embodiments, the buffer layers, that is, the air gap layers, having low permittivity may be formed between the conductor patterns, thereby decreasing permittivity of the electronic component.

In a case in which the permittivity of the electronic component is decreased by forming the buffer layers, that is, the air gap layers, having low permittivity between the conductor patterns, as described above, the parasitic capacitance of the electronic component may be decreased, such that the Q factor of the electronic component may be improved.

While exemplary embodiments have been shown and described above, it will be apparent to those skilled in the art that modifications and variations could be made without departing from the scope of the present invention as defined by the appended claims.

What is claimed is:

1. An electronic component comprising:
a multilayer body including a plurality of magnetic or dielectric layers and a coil part including a plurality of conductor patterns and conductive vias electrically connecting the plurality of conductor patterns to each other; and
external electrodes disposed on outer surfaces of the multilayer body and electrically connected to the coil part,
wherein adjacent conductor patterns have at least one among the magnetic or dielectric layers interposed therebetween, and
buffer layers having a permittivity lower than that of the multilayer body are disposed at interfaces between the conductor patterns and the magnetic or dielectric layers.

2. The electronic component of claim 1, wherein a ratio of a permittivity of the multilayer body to the permittivity of the buffer layer is 4 to 7.

3. The electronic component of claim 1, wherein the buffer layer is an air gap layer having a relative permittivity of 1.0.

4. The electronic component of claim 1, wherein the magnetic or dielectric layers contain ferrite or magnetic metal powder.

5. An electronic component comprising:
a multilayer body including a plurality of magnetic or dielectric layers and a coil part including a plurality of conductor patterns and conductive vias electrically connecting the plurality of conductor patterns to each other; and
external electrodes disposed on outer surfaces of the multilayer body and electrically connected to the coil part,
wherein adjacent conductor patterns have at least one among the magnetic or dielectric layers interposed therebetween, and
air gap layers are disposed at interfaces between the conductor patterns and the magnetic or dielectric layers.

6. The electronic component of claim 5, wherein a ratio of a permittivity of the multilayer body to a permittivity of the air gap layer is 4 to 7.

7. The electronic component of claim 5, wherein the magnetic or dielectric layers contain ferrite or magnetic metal powder.

8. A board having an electronic component, comprising:
a printed circuit board on which first and second electrode pads are disposed; and
the electronic component of claim 1 mounted on the printed circuit board.

9. The board of claim 8, wherein a ratio of the permittivity of the multilayer body to the permittivity of the buffer layer is 4 to 7.

10. The board of claim 8, wherein the buffer layer is an air gap layer having a relative permittivity of 1.0.

11. The board of claim 8, wherein the magnetic or dielectric layers contain ferrite or magnetic metal powder.
